(19) United States
(12) Patent Application Publication
(10) Pub. No.: US 2012/0194286 A1
(43) Pub. Date: Aug. 2, 2012

(54) METHODS AND SYSTEMS FOR MEMS CMOS DEVICES HAVING ARRAYS OF ELEMENTS

(75) Inventor: Josep Montanya Silvestre, Rubi (ES)

(73) Assignee: Baolab Microsystems SL, Terrassa (ES)

(21) Appl. No.: 13/364,149

(22) Filed: Feb. 1, 2012

Related U.S. Application Data
(60) Provisional application No. 61/438,558, filed on Feb. 1, 2011.
(60) Provisional application No. 61/440,223, filed on Feb. 7, 2011.
(60) Provisional application No. 61/496,403, filed on Jun. 13, 2011.
(60) Provisional application No. 61/501,950, filed on Jun. 28, 2011.
(60) Provisional application No. 61/558,689, filed on Nov. 11, 2011.

(51) Int. Cl. H03L 7/00; H01L 29/84; H01L 21/02

(52) U.S. Cl. 331/36 C; 438/50; 257/415; 257/E29.324; 257/E21.002

(57) ABSTRACT

Systems and methods for manufacturing a chip comprising a plurality of MEMS devices arranged in an integrated circuit are provided. In one aspect, the systems and methods provide for a chip including electronic elements formed on a semiconductor material substrate. The chip further includes a stack of interconnection layers including layers of conductor material separated by layers of dielectric material. MEMS devices are formed within the stack of interconnection layers by applying gaseous HF to a first layer of dielectric material positioned highest in the stack of interconnection layers. The stack of interconnection layers includes at least one unetched layer of dielectric material, and at least one layer of conductor material for routing connections to and from the electronic elements.

### CROSS REFERENCE TO RELATED APPLICATIONS

This application claims priority to U.S. Provisional Patent Application No. 61/438,558 filed Feb. 1, 2011, U.S. Provisional Patent Application No. 61/440,223 filed Feb. 7, 2011, U.S. Provisional Patent Application No. 61/496,403 filed Jun. 13, 2011, U.S. Provisional Patent Application No. 61/501,950 filed Jun. 28, 2011, and U.S. Provisional Patent Application No. 61/558,689 filed Nov. 11, 2011, all of which are incorporated herein by reference in their entirety.

### BACKGROUND

An integrated circuit is a semiconductor device that has a substrate of a semiconductor material on which a series of layers are deposited using photolithographic techniques. The layers are doped, polarized and attacked, so that electrical elements (e.g., resistances, capacitors, or impedances) or electronic elements (e.g., diodes or transistors) are produced. Subsequently other layers are deposited, which form the structure of interconnection layers necessary for electrical connections.

A chip may include a micro-electro-mechanical system (MEMS) device and an integrated circuit, where the integrated circuit may control the MEMS. There are various techniques for manufacturing a chip that includes both a MEMS and an integrated circuit. One technique includes fabricating MEMS devices within the interconnection layers of the integrated circuit using most or all interconnection layers. However, this technique leaves little room in the interconnection layers for routing to and from electronic elements also on the integrated circuit. As a result, any silicon area of the chip allocated to the MEMS device typically cannot be used for routing and, thus, adds to the silicon area required to fabricate the integrated circuit.

Accordingly, there is a need for a technique of fabricating MEMS devices within interconnection layers of an integrated circuit that allows for more judicious use of the silicon area of the chip.

### SUMMARY

The systems and methods described herein address deficiencies in the prior art by enabling fabrication of MEMS devices within interconnection layers of an integrated circuit without using most or all interconnection layers. In particular, systems and methods described herein provide for fabricating a MEMS device within the interconnection layers of an integrated circuit using at most two layers of conductor material.

In some embodiments, a chip includes a MEMS device formed within a stack of interconnection layers of an integrated circuit. The stack includes, e.g., six layers of conductor material separated by six layers of dielectric material, where the top layer is a layer of conductor material (sometimes referred to as the capping). The MEMS device is formed within the stack of interconnection layers by applying gaseous HF to at least a layer of dielectric material positioned highest in the stack. As a result, the MEMS device is released within the two layers of conductor material highest in the stack. However, the remaining layers of dielectric material are unetched, and one or more of the remaining layers of conductor material may be used for routing connections. Accordingly, a MEMS device may be fabricated within a stack of interconnection layers of an integrated circuit while still allowing for routing connections within the lower layers of the stack, thereby reducing silicon area needed for the chip.

The described approach may also be beneficial for fabricating a MEMS device within a stack of interconnection layers of an integrated circuit when using complementary metal oxide semiconductor (CMOS) fabrication processes including low-k dielectric materials, e.g., 130 nm or lower CMOS processes. Low-k dielectric materials have a dielectric constant lower than silicon dioxide, and are typically difficult to etch compared to silicon dioxide when using, e.g., gaseous HF. A layer of silicon dioxide dielectric material may be included as the highest layer of dielectric material in the stack, while the remaining layers may include low-k dielectric material. The MEMS device may be formed within the stack of interconnection layers by applying gaseous HF to the layer of silicon dioxide dielectric material, without need for etching any of the layers of low-k dielectric material. Additionally, etching using gaseous HF may provide relatively uniform results, and provide higher yield when fabricating such MEMS devices. Etching fewer layers during fabrication may also reduce etching byproducts and reduce risk of corrosion to the MEMS device, thereby improving long-term reliability.

The described approach also offers certain other advantages. For example, any supporting anchors for the MEMS device may require less area within the interconnection layers due to the MEMS device being partially supported by the unetched layers in the stack. This may also reduce parasitic capacitances typically observed when a MEMS device is fabricated within most or all interconnection layers of an integrated circuit.

In certain cases, a MEMS device fabricated within interconnection layers of an integrated circuit using the described approach may not have the sensitivity required for its intended application. This is because the MEMS element released from the layers of conductor material may not have a sufficient length or mass. For example, a MEMS accelerometer may require a certain proof mass for use in its intended environment. In order to achieve a critical mass or length for the MEMS device to have the target sensitivity, an array of MEMS devices may be fabricated within the interconnection layers. For example, an array of MEMS accelerometers having a appropriate combined proof mass may be used as an accelerometer having the required proof mass.

Furthermore, due to silicon area savings from the described approach, multiple arrays of MEMS devices may be fabricated in the interconnection layers and disposed above an application specific integrated circuit (ASIC) that can selectively control the arrays. In some embodiments, multiple arrays each having a different type of MEMS device are fabricated and then the ASIC may switch between each array as required. For example, a reconfigurable motion sensor cell may be formed that includes an accelerometer array, a gyroscope array, and a magnetometer array fabricated within the interconnection layers of the ASIC. The motion sensor cell's ASIC may then select whether the motion sensor cell should offer the functionality of an accelerometer, a gyroscope, or a magnetometer.

In some embodiments, a single type of MEMS device is fabricated above the ASIC. Certain devices may be initially unused and reserved for redundancy in case of failure of another in-use device. In case of failure of a device due to issues during fabrication, the redundant device may help improve yield. In case of failure of a device during operation, the redundant device may help improve long-term reliability. In some embodiments, a hybrid motion sensor is built having redundant elements as well multiple types of device arrays, thereby offering the combined benefits of reconfigurability, redundancy, and reliability.

In one aspect, the systems and methods described herein provide for a method for manufacturing a chip including MEMS devices arranged in an integrated circuit. The method includes forming electronic elements on a semiconductor material substrate. The method further includes forming above the semiconductor material substrate a stack of interconnection layers including layers of conductor material separated by layers of dielectric material. The method further includes forming MEMS devices within the stack of interconnection layers by applying gaseous HF to a first layer of dielectric material positioned highest in the stack of interconnection layers, while allowing at least one layer of dielectric material to remain unetched, and allowing at least one layer of conductor material for routing connections to and from the electronic elements.

In some embodiments, the unetched layer of the dielectric material is the lowest layer of the dielectric material in the stack. In some embodiments, the chip is manufactured using a 180 nm or lower CMOS process. In some embodiments, the chip is manufactured using one of a 22 nm CMOS process, a 32 nm CMOS process, a 45 nm CMOS process, and a 65 nm CMOS process.

In some embodiments, the highest layer of conductor material in the stack includes aluminum. In some embodiments, the first layer of dielectric material includes silicon dioxide. In some embodiments, the method further includes forming at least one anchor within the layers of conductor material for supporting a MEMS device or a top layer of the plurality of layers of conductor material.

In some embodiments, the MEMS devices are of a same type. In some embodiments, the MEMS devices comprises a first device and second device, and the second device is reserved for redundancy in case of failure of the first device. In some embodiments, the MEMS devices are of different types including a magnetometer, a gyroscope, or an accelerometer.

In some embodiments, the MEMS devices include a sensor array of MEMS devices that is configured to collectively operate as a resonator. In some embodiments, the sensor array includes about 60 to about 200 MEMS devices. In some embodiments, the sensor array includes a first set of MEMS devices configured to collectively operate as a first type of device and a second set of MEMS devices configured to collectively operate as a second type of device. The sensor array is reconfigurable from operating as the first type of device to operating as the second type of device. In some embodiments, the sensor array is densely formed in a small area of the interconnection layers to reduce frequency mismatch between the MEMS devices in the sensor array. In some embodiments, the sensor array has a Q factor of 100 or higher. In some embodiments, the sensor array has a Q factor ranging from about 5 to about 20.

In another aspect, the systems and methods described herein provide for a chip including electronic elements formed on a semiconductor material substrate. The chip further includes above the semiconductor material substrate a stack of interconnection layers including layers of conductor material separated by layers of dielectric material. MEMS devices are formed within the stack of interconnection layers by applying gaseous HF to a first layer of dielectric material positioned highest in the stack of interconnection layers, while allowing for at least one unetched layer of dielectric material to remain unetched, and allowing at least one layer of conductor material for routing connections to and from the electronic elements.

In some embodiments, the unetched layer of the dielectric material is the lowest layer of the dielectric material in the stack. In some embodiments, the chip is manufactured using a 180 nm or lower CMOS process. In some embodiments, the chip is manufactured using one of a 22 nm CMOS process, a 32 nm CMOS process, a 45 nm CMOS process, and a 65 nm CMOS process.

In some embodiments, the highest layer of conductor material in the stack includes aluminum. In some embodiments, the first layer of dielectric material includes silicon dioxide. In some embodiments, the chip further includes at least one anchor within the layers of conductor material for supporting a MEMS device or a top layer of the plurality of layers of conductor material.

In some embodiments, the MEMS devices are of a same type. In some embodiments, the MEMS devices comprises a first device and second device, and the second device is reserved for redundancy in case of failure of the first device. In some embodiments, the MEMS devices are of different types including a magnetometer, a gyroscope, or an accelerometer.

In some embodiments, the MEMS devices include a sensor array of MEMS devices that is configured to collectively operate as a resonator. In some embodiments, the sensor array includes about 60 to about 200 MEMS devices. In some embodiments, the sensor array includes a first set of MEMS devices configured to collectively operate as a first type of device and a second set of MEMS devices configured to collectively operate as a second type of device. The sensor array is reconfigurable from operating as the first type of device to operating as the second type of device. In some embodiments, the sensor array is densely formed in a small area of the interconnection layers to reduce frequency mismatch between the MEMS devices in the sensor array. In some embodiments, the sensor array has a Q factor of 100 or higher. In some embodiments, the sensor array has a Q factor ranging from about 5 to about 20.

In yet another aspect, the systems and methods described herein provide for a method for manufacturing a chip including MEMS devices arranged in an integrated circuit. The method includes forming electronic elements on a semiconductor material substrate. The method further includes forming above the semiconductor material substrate a stack of interconnection layers including layers of conductor material separated by layers of dielectric material. The method further includes forming the MEMS devices within the stack of interconnection layers by applying gaseous HF to a first layer of dielectric material positioned highest in the stack of interconnection layers, while allowing at least one layer of dielectric material to remain unetched. The chip is manufactured in a CMOS process including low-k dielectric material having a dielectric constant lower than silicon dioxide. The first layer of dielectric material includes silicon dioxide and the at least one unetched layer of dielectric material includes low-k dielectric material. In some embodiments, the CMOS process is a 130 nm or lower CMOS process.

In yet another aspect, the systems and methods described herein provide for a chip including MEMS devices arranged in an integrated circuit. The chip includes electronic elements formed on a semiconductor material substrate. The chip further includes produced above the semiconductor material substrate a stack of interconnection layers including layers of conductor material separated by layers of dielectric material. The chip further includes MEMS devices formed within the stack of interconnection layers by applying gaseous HF to a first layer of dielectric material positioned highest in the stack of interconnection layers, while allowing at least one layer of dielectric material to remain unetched. The chip is manufactured in a CMOS process including low-k dielectric material having a dielectric constant lower than silicon dioxide. The first layer of dielectric material includes silicon dioxide and the at least one unetched layer of dielectric material includes low-k dielectric material. In some embodiments, the CMOS process is a 130 nm or lower CMOS process.

In yet another aspect, the systems and methods described herein provide for a MEMS resonator device including a resonator element, a supporting member attached to the resonator element, and a calibration element disposed proximate to the resonator element. The resonator element is calibrated based on a magnetic field generated on passing current through the calibration element.

In some embodiments, the resonator element is formed within a first layer of conductor material, and the calibration element is formed within a second adjacent layer of conductor material. The resonator element is further calibrated based on a capacitance generated between the first layer of conductor material and the second layer of conductor material. The capacitance aids in determining a distance between the calibration element and the resonator element.

In some embodiments, the MEMS resonator device further includes a first capacitive element disposed within the first layer of conductor material, and a second capacitive element disposed within the second adjacent layer of conductor material. The resonator element is further calibrated based on a first capacitance of the first capacitive element. The first capacitance aids in determining a thickness of the first layer of conductor material. The resonator element is further calibrated based on a second capacitance of the second capacitive element. The second capacitance aids in determining a thickness of the second layer of conductor material.

In some embodiments, the calibration element includes a metal wire disposed proximate to the resonator element in a parallel fashion. In some embodiments, the calibration element includes an inductor disposed proximate to the resonator element. In some embodiments, a portion of the calibration element is disposed in an unetched layer of dielectric material. In some embodiments, the resonator element includes a magnetometer, and calibrating the resonator element includes calibrating a gain of the magnetometer.

In yet another aspect, the systems and methods described herein provide for a method of calibrating a MEMS resonator device. The MEMS resonator device includes a resonator element formed within a first layer of conductor material, a supporting member attached to the resonator element, and a calibration element formed within a second adjacent layer of conductor material. The calibration element disposed proximate to the resonator element. The method includes applying a current to the calibration element to generate a magnetic field, and measuring a capacitance generated between the first layer of conductor material and the second layer of conductor material. The capacitance aids in determining a distance between the calibration element and the resonator element. The method further includes calibrating the resonator element based on the magnetic field and the measured capacitance.

In some embodiments, the MEMS resonator device includes a first capacitive element disposed within the first layer of conductor material, and a second capacitive element disposed within the second adjacent layer of conductor material. The method further includes calibrating the resonator element based on a first capacitance of the first capacitive element. The first capacitance aids in determining a thickness of the first layer of conductor material. The method further includes calibrating the resonator element based on a second capacitance of the second capacitive element. The second capacitance aids in determining a thickness of the second layer of conductor material.

In yet another aspect, the systems and methods described herein provide for a method for manufacturing a chip including anchors arranged in an integrated circuit. The method includes forming electronic elements on a semiconductor material substrate. The method further includes forming a stack of interconnection layers above the semiconductor material substrate. The stack of interconnection layers includes layers of conductor material separated layers of dielectric material. The method further includes forming the anchors within the stack of interconnection layers by applying gaseous HF to a first layer of dielectric material in the stack of interconnection layers, while allowing a layer of dielectric material to remain unetched, and allowing a layer of conductor material for routing connections to and from the electronic elements. Each anchor includes conductor layer portions from the layers of conductor material separated by vias. Each anchor supports a top layer of conductor material or a MEMS device formed within the stack of interconnection layers.

In some embodiments, a portion of an anchor includes dielectric material that replaces conductor material or via. In some embodiments, an anchor is formed according to a CMOS process design rule violation. The design rule violation may include conductor layer portions and vias that are substantially similar in width and do not overlap. The design rule violation may include vias that are wider than a width according to the CMOS process.

In yet another aspect, the systems and methods described herein provide for a chip including anchors arranged in an integrated circuit. The chip includes electronic elements formed on a semiconductor material substrate. The chip further includes a stack of interconnection layers formed above the semiconductor material substrate. The stack of interconnection layers includes layers of conductor material separated layers of dielectric material. The chip further includes the anchors formed within the stack of interconnection layers by applying gaseous HF to a first layer of dielectric material in the stack of interconnection layers, while allowing a layer of dielectric material to remain unetched, and allowing a layer of conductor material for routing connections to and from the electronic elements. Each anchor includes conductor layer portions from the layers of conductor material separated by vias. Each anchor supports a top layer of conductor material or a MEMS device formed within the stack of interconnection layers.

In some embodiments, a portion of an anchor includes dielectric material that replaces conductor material or via. In some embodiments, an anchor is formed according to a CMOS process design rule violation. The design rule violation may include conductor layer portions and vias that are substantially similar in width and do not overlap. The design rule violation may include vias that are wider than a width according to the CMOS process.

### BRIEF DESCRIPTION OF THE DRAWINGS

Other advantages and characteristics of the systems and methods described herein may be appreciated from the following description, which provides a non-limiting description of illustrative embodiments, with reference to the accompanying drawings, in which:

FIG. 1 depicts a cross-section of a process flow step during fabrication of a MEMS device of an array, according to an illustrative embodiment of the invention;

FIG. 2A depicts a cross-section of a process flow step during fabrication of a MEMS device of an array, according to another illustrative embodiment of the invention;

FIG. 2B depicts a cross-section of a process flow step during fabrication of a MEMS device of an array, according to yet another illustrative embodiment of the invention;

FIG. 3 depicts a flow diagram for fabricating a chip having an array of MEMS devices arranged in an integrated circuit, according to an illustrative embodiment of the invention;

FIG. 4A depicts a cross-section after a first set of process flow steps for fabricating a MEMS device of an array, according to an illustrative embodiment of the invention;

FIG. 4B depicts a cross-section after a second set of process flow steps for fabricating a MEMS device of an array, according to an illustrative embodiment of the invention;

FIG. 4C depicts a cross-section after a third set of process flow steps for fabricating a MEMS device of an array, according to an illustrative embodiment of the invention;

FIG. 5A depicts a perspective view of a partially fabricated MEMS device of an array, according to an illustrative embodiment of the invention;

FIG. 5B depicts a perspective view of a fabricated MEMS device of an array, according to an illustrative embodiment of the invention;

FIG. 5C shows a column anchor for supporting a capping and/or a MEMS device, according to an illustrative embodiment of the invention;

FIG. 5D shows a column anchor for supporting a capping and/or a MEMS device, according to another illustrative embodiment of the invention;

FIG. 5E shows a column anchor for supporting a capping and/or a MEMS device, according to yet another illustrative embodiment of the invention;

FIG. 5F shows a column anchor for supporting a capping and/or a MEMS device, according to yet another illustrative embodiment of the invention;

FIG. 5G shows a column anchor for supporting a capping and/or a MEMS device, according to yet another illustrative embodiment of the invention;

FIG. 6A depicts a diagrammatic view of an array of MEMS devices, according to an illustrative embodiment of the invention;

FIG. 6B depicts a diagrammatic view of a reconfigurable array of MEMS devices, according to an illustrative embodiment of the invention;

FIG. 6C depicts a perspective view of an array of MEMS devices, according to an illustrative embodiment of the invention;

FIG. 7A depicts a diagrammatic view of a chip having an array of MEMS devices arranged in an integrated circuit, according to an illustrative embodiment of the invention;

FIG. 7B depicts a diagrammatic view of a chip having an array of MEMS devices arranged in an integrated circuit, according to another illustrative embodiment of the invention;

FIG. 8A depicts a diagrammatic view of a resonator element, according to an illustrative embodiment of the invention;

FIG. 8B depicts diagrammatic views of various resonator elements, according to an illustrative embodiment of the invention; and

FIG. 8C depicts a perspective view of MEMS resonator device including a resonator element and a calibration element disposed proximate to the resonator element, according to an illustrative embodiment of the invention.

### DETAILED DESCRIPTION OF EMBODIMENTS

To provide an overall understanding of the systems and methods described herein, certain illustrative embodiments will now be described. However, it will be understood by one of ordinary skill in the art that the systems and methods described herein may be adapted and modified as is appropriate for the application being addressed and that the systems and methods described herein may be employed in other suitable applications, and that such other additions and modifications will not depart from the scope thereof.

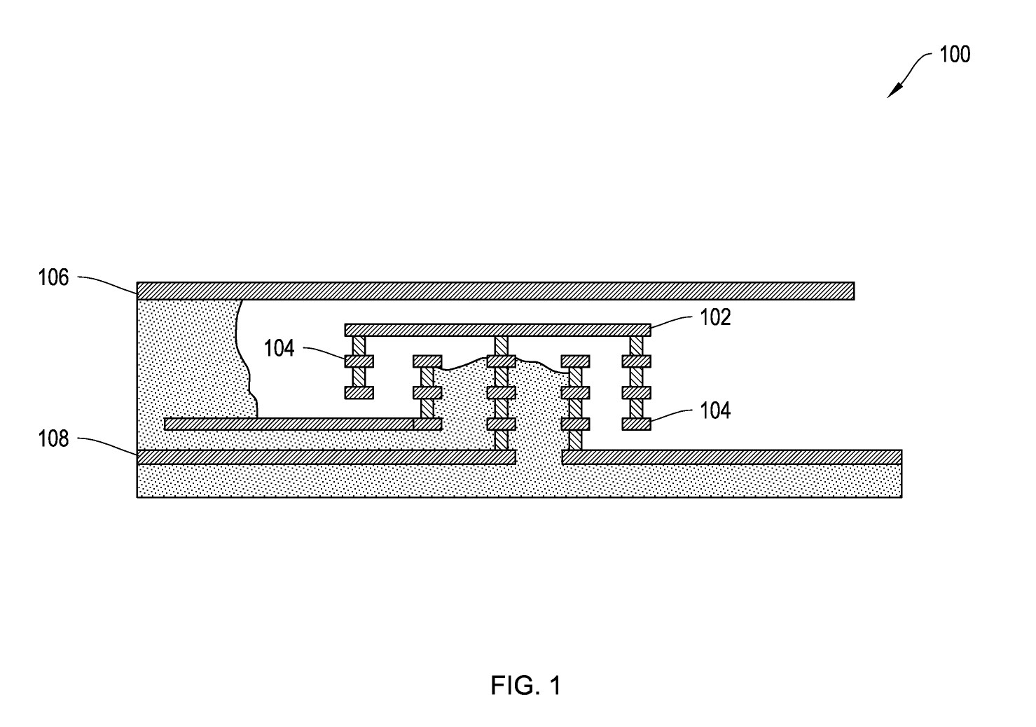

FIG. 1 depicts a typical cross-section of a MEMS device 100 fabricated within interconnection layers of an integrated circuit. The MEMS device 100 is fabricated within all six metal (or conductor material) layers of the stack of interconnection layers, including top metal layer 106 and bottom metal layer 108. The MEMS device 100 includes element 102 supported by anchors 104. However, this technique leaves no room in the interconnection layers, e.g., metal layer 108, for routing to and from electronic elements also on the integrated circuit. As a result, any silicon area of the chip allocated to the MEMS device 100 typically cannot be used for routing and, thus, adds to the silicon area required to fabricate the integrated circuit.

The configuration of FIG. 1 may also be disadvantageous for long-term reliability. In the embodiment shown, long metal planes and continuous vias are used to limit horizontal etching and vertical etching, respectively, of interconnection layers by gaseous HF. However, such a complex structure may force the gaseous HF to travel through long paths and prevent undesired etching of the interconnection layers. Furthermore, this approach may allow water molecules produced as a byproduct of the etching reaction to become trapped causing corrosion and long-term reliability issues.

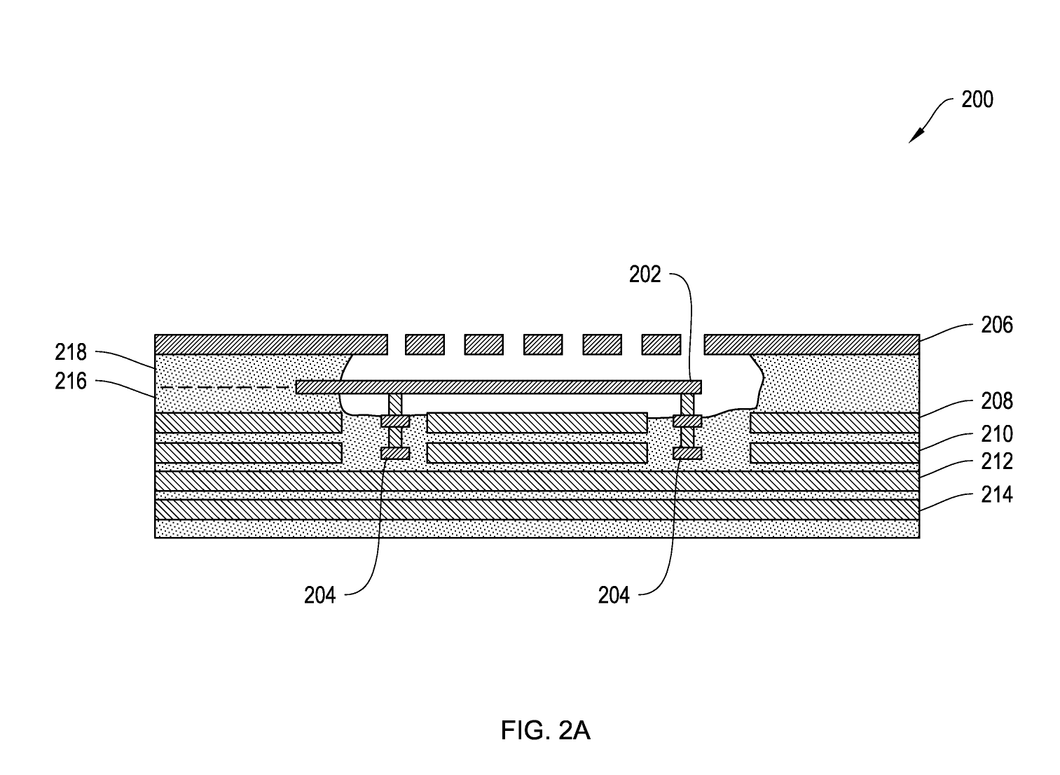

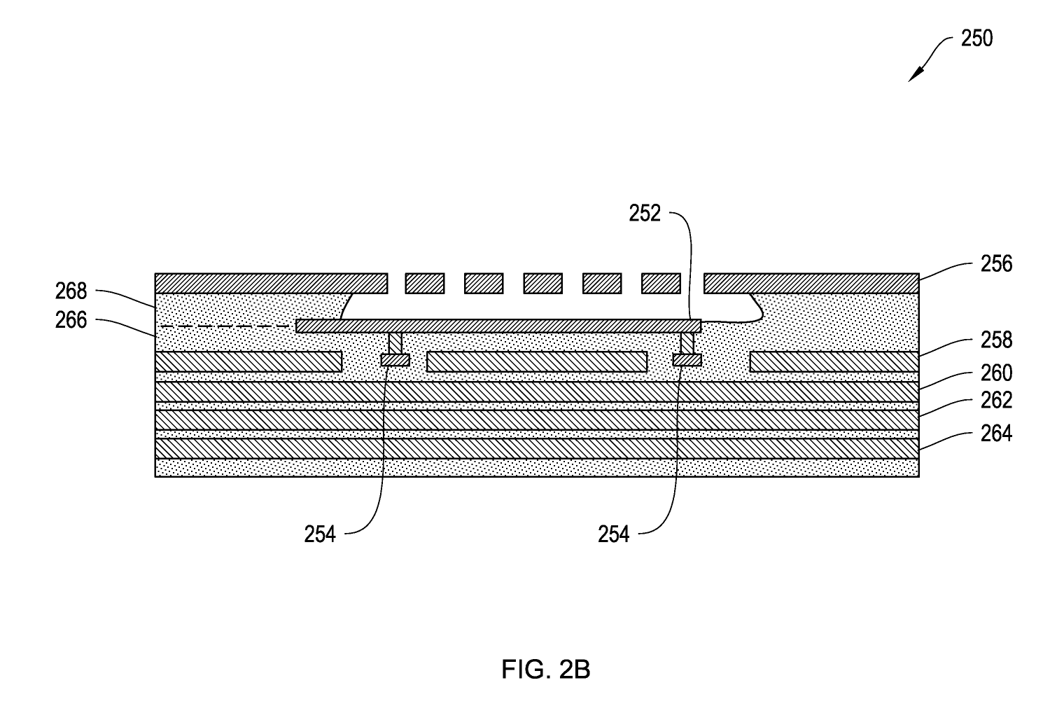

FIG. 2A depicts an illustrative cross-section of a MEMS device 200 fabricated within two metal layers of the stack of interconnection layers. The stack includes six metal layers separated by six layers of dielectric material, where the top layer 206 is a layer of conductor material (sometimes referred to as the capping). The MEMS device 200 is formed within the stack of interconnection layers by applying gaseous HF to the two layers of dielectric material 216 and 218 positioned highest in the stack. As a result, the MEMS device 200 is released within the two layers of conductor material 202 and 206 highest in the stack. However, the remaining layers of dielectric material are unetched, and one or more of the remaining layers of conductor material 208, 210, 212, or 214, may be used for routing connections. Though layers 208 and 210 include anchors 204 for supporting the MEMS device 200, they may still be used for routing connections because of the small space required for the anchors 204. In some embodiments, the anchors 204 are implemented within two layers of conductor material to account for variation (around 10%) in height of layers in CMOS processes. Accordingly, a MEMS device may be fabricated within a stack of interconnection layers of an integrated circuit while still allowing for routing connections within the lower layers of the stack, thereby reducing silicon area needed for the chip. In one example, this configuration may be used to fabricate a resonator element for an accelerometer or a gyroscope.

FIG. 2B depicts another illustrative cross-section of a MEMS device 250 fabricated within two metal layers of the stack of interconnection layers. The stack includes six metal layers separated by six layers of dielectric material, where the top layer 256 is a layer of conductor material (sometimes referred to as the capping). The MEMS device 250 is formed within the stack of interconnection layers by applying gaseous HF. The gaseous HF etches one layer of dielectric material 268 positioned highest in the stack. As a result, the MEMS device 250 is released within the two layers of conductor material 252 and 256 highest in the stack. However, the remaining layers of dielectric material, including layer 266, are unetched. One or more of the remaining layers of conductor material 258, 260, 262, or 264, may be used for routing connections. Though layer 258 includes anchors 254 for supporting the MEMS device 250, it may still be used for routing connections because of the small space required for the anchors 254. This configuration may be advantageous over the configuration of FIG. 2A because the unetched layer of dielectric material 268 provides support to MEMS device 250. Accordingly, only smaller one-level anchors 254 are needed to further support MEMS device 250. In some embodiments, the unetched layer of dielectric material 268 only supports the MEMS device 250, eliminating the need for anchors. In one example, this configuration may be used to fabricate a sensor element for a pressure sensor.

The configurations described with respect to FIGS. 2A and 2B may also be beneficial for fabricating a MEMS device within a stack of interconnection layers of an integrated circuit when using complementary metal oxide semiconductor (CMOS) fabrication processes including low-k dielectric materials, e.g., 130 nm or lower CMOS processes. Such processes may provide advantages such as smaller die area, lower cost, and lower power consumption, compared to CMOS processes higher than 130 nm. Low-k dielectric materials have a dielectric constant lower than silicon dioxide, and are typically difficult to etch compared to silicon dioxide when using, e.g., gaseous HF. A layer of silicon dioxide dielectric material may be included as the highest layer of dielectric material in the stack, while the remaining layers may include low-k dielectric material. The MEMS device may be formed within the stack of interconnection layers by applying gaseous HF to the layer of silicon dioxide dielectric material, without need for etching any of the layers of low-k dielectric material.

Additionally, etching using gaseous HF may provide relatively uniform results, and provide higher yield when fabricating such MEMS devices. Etching fewer layers during fabrication may also reduce etching byproducts and reduce risk of corrosion to the MEMS device, thereby improving long-term reliability. In some embodiments, a time based stop may be used to limit etching of the interconnection layers by gaseous HF. Without adding any complex structures as described with respect to FIG. 1, etching via gaseous HF may be limited by stopping the etching after a very short period of time. This approach may afford minimum risk of corrosion due to trapped water molecules produced as a byproduct of the etching reaction. Both FIGS. 2A and 2B are illustrative embodiments of this approach to form a MEMS device.

The configurations described with respect to FIGS. 2A and 2B also offer certain other advantages. For example, any supporting anchors for the MEMS device may require less area within the interconnection layers due to the MEMS device being partially supported by the unetched layers in the stack. This may also reduce parasitic capacitances typically observed when a MEMS device is fabricated within most or all interconnection layers of an integrated circuit.

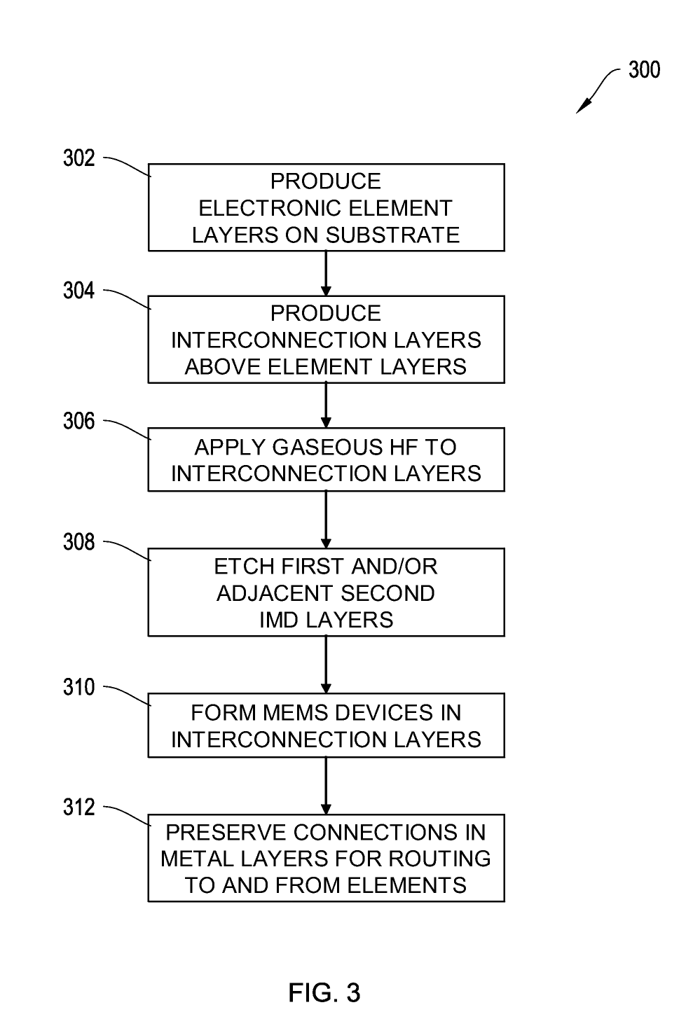

FIG. 3 depicts an illustrative flow diagram 300 for fabricating a chip having an array of MEMS devices arranged in an integrated circuit. The chip is manufactured using a 180 nm or lower CMOS process, e.g., a 22 nm CMOS process, a 32 nm CMOS process, a 45 nm CMOS process, or a 65 nm CMOS process. At step 302, electronic elements are formed on a semiconductor material substrate. At step 304, a stack of interconnection layers including layers of conductor material separated by layers of dielectric material is formed above the semiconductor material substrate. At step 306, gaseous HF is applied to the interconnection layers. At step 308, a first layer of dielectric material positioned highest in the stack of interconnection layers is etched. In some embodiments, the first layer of dielectric material includes silicon dioxide. A second adjacent layer of dielectric material may also be etched. At least one layer of dielectric material remains unetched. In some embodiments, the unetched layer of the dielectric material is the lowest layer of the dielectric material in the stack. At step 310, the MEMS devices are released within the stack of interconnection layers. In some embodiments, the MEMS devices are of a same type. In some embodiments, the MEMS devices comprises a first device and second device, and the second device is reserved for redundancy in case of failure of the first device. In some embodiments, the MEMS devices are of different types including a magnetometer, a gyroscope, or an accelerometer. One or more anchors for supporting a MEMS device or a top layer of the plurality of layers of conductor material may also be formed within the layers of conductor material. At step 312, routing connections to and from the electronic elements remain formed in at least one layer of conductor material.

Described below are process flow steps for fabricating a MEMS device of an array via a CMOS MEMS-based process. For example, the MEMS device may be fabricated using a CMOS MEMS-based process described in commonly-owned U.S. Patent Application Publication No. 2010/0295138, entitled “Methods and Systems for Fabrication of MEMS CMOS Devices.” However, fabrication processes for the MEMS device need not be limited to CMOS MEMS-based processes, and may include MEMS-based processes, NEMS-based processes, and other suitable processes.

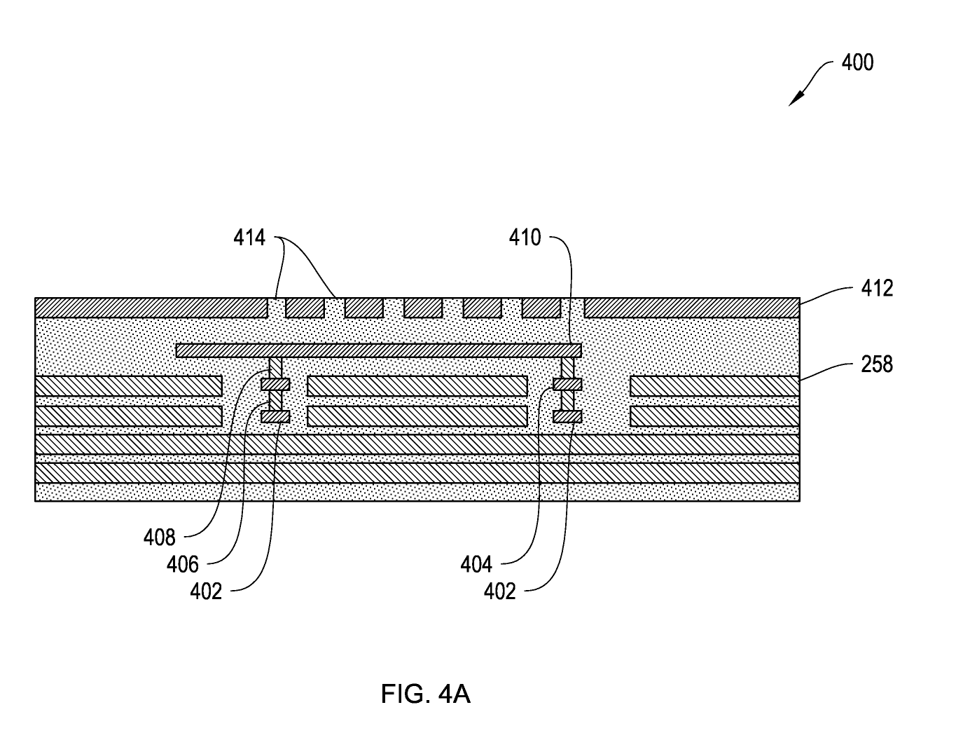

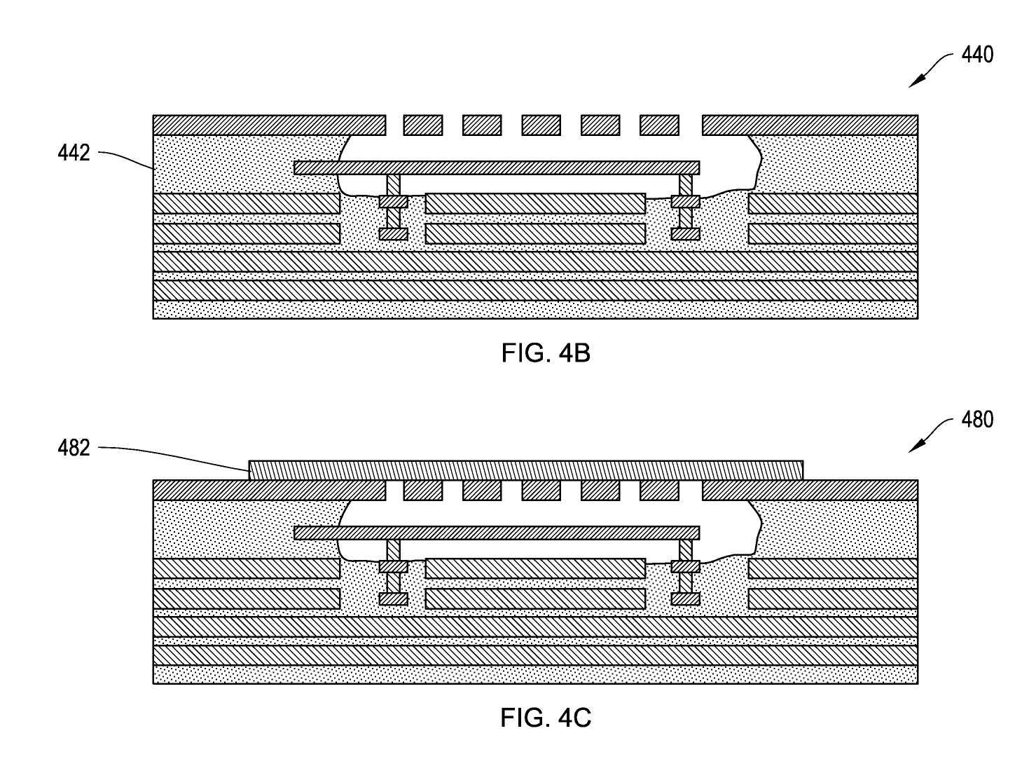

FIG. 4A depicts an illustrative cross-section after a first set of process flow steps for fabricating a MEMS device of an array. The thickness of the layers has been magnified. In one embodiment, the MEMS device is fabricated using a standard CMOS process. In one embodiment, the MEMS device is fabricated in a cavity formed within interconnection layers of a CMOS chip. In an alternative embodiment, the MEMS device is fabricated as a stand-alone MEMS device. Initially a metal layer is deposited. The metal layer can be made from, e.g., AlCu metal alloy. A masking layer is deposited above the metal layer, and then the metal layer is etched using, e.g., dry HF, to form plates 402. An Inter Metal Dielectric (IMD) layer is deposited above plates 402, followed by a masking layer, and then the IMD layer is etched and filled with metal to form spacers or vias 404. In one embodiment, the IMD layer includes a layer of non-doped oxide. Another metal layer is deposited, followed by a masking layer deposited above the metal layer, and then the metal layer is etched using, e.g., dry HF, to form plates 406. Another IMD layer is deposited above plates 406, followed by a masking layer, and then the IMD layer is etched and filled with metal to form spacers or vias 408. Plates 402 and 404 and spacers 406 and 408 together form anchors for the MEMS device. A metal layer is deposited on spacers 408 to form bridge 410 of the MEMS device. Another IMD layer is deposited on bridge 410, followed by top metal layer 412. A masking layer is deposited on top metal layer 412. Top metal layer 412 is then etched to form through-holes 414. The through-holes can allow passage of etchant, e.g., gaseous HF, to etch material below top metal layer 412.

FIGS. 4B and 4C depict cross-sections after a second and a third set of process flow steps, respectively, for fabricating a MEMS device of an array. An etchant, e.g., dry HF, is released via through-holes 414 in top metal layer 412. The etchant etches away portions of the IMD layers to release the anchors and bridge of the MEMS device, as shown in FIG. 4B. Bottom plates 402 are buried in the remaining oxide 442 of IMD layers to provide support to the MEMS device. Finally, metallization layer 482 is deposited on top metal layer 412 to seal the MEMS device from the outside environment, as shown in FIG. 4C. In one embodiment, the MEMS device is fabricated using MEMS-based, NEMS-based, or MEMS CMOS-based integrated chip technology.

In some embodiments, a MEMS device is arranged in an integrated circuit. The process flow steps of FIGS. 4A-4C are performed in the interconnection layers of the integrated circuit. Layers that form electrical and/or electronic elements on a semiconductor material substrate are produced. Interconnection layers including a bottom layer of conductor material and a top layer of conductor material, separated by at least one layer of dielectric material, are produced. A portion of the MEMS device is formed within the interconnection layers by applying gaseous HF to the at least one layer of dielectric material in accordance with the process flow steps described with respect to FIGS. 4A-4C.

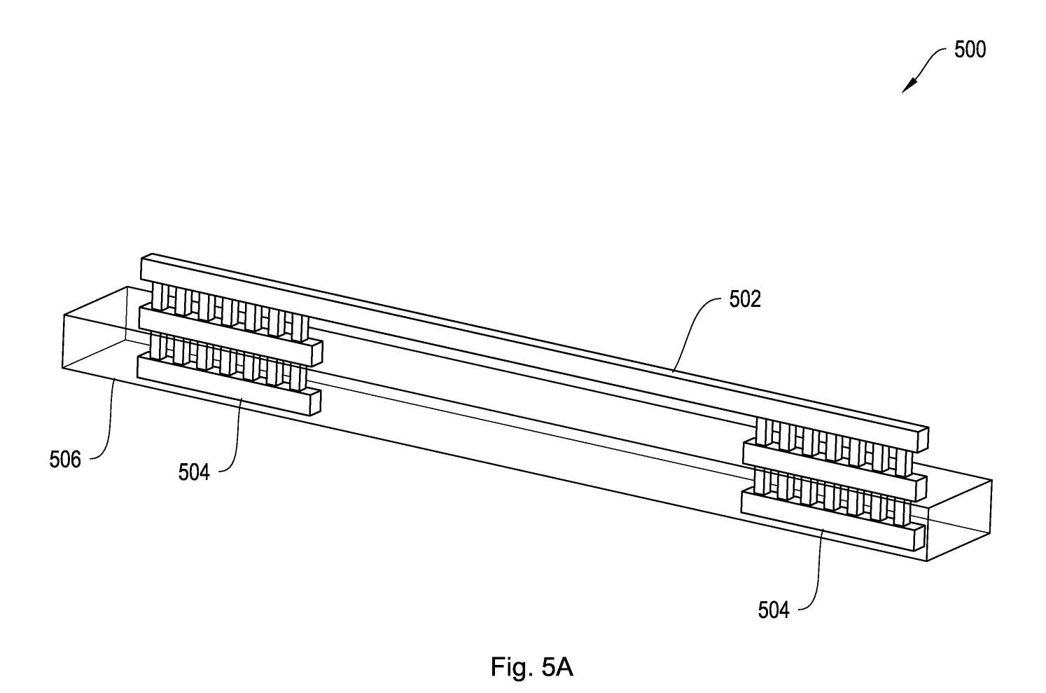

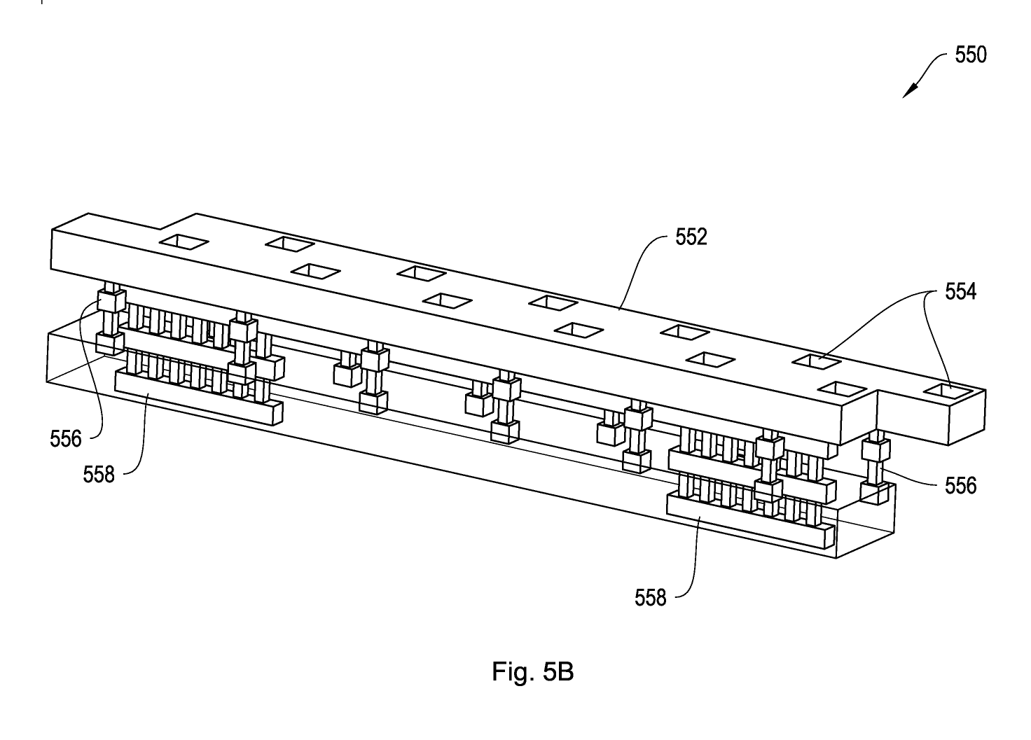

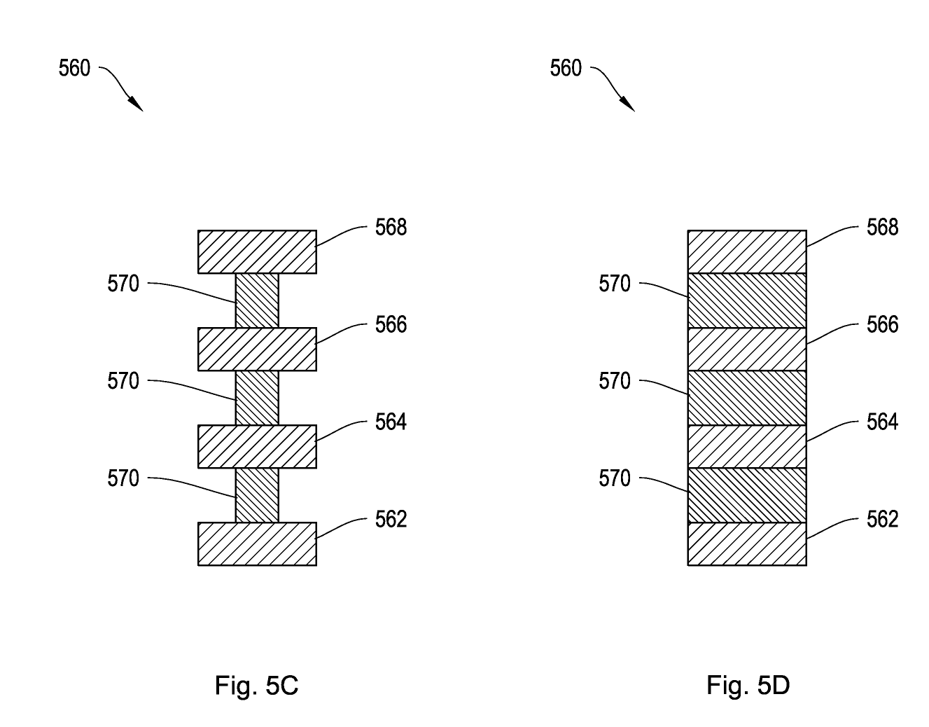

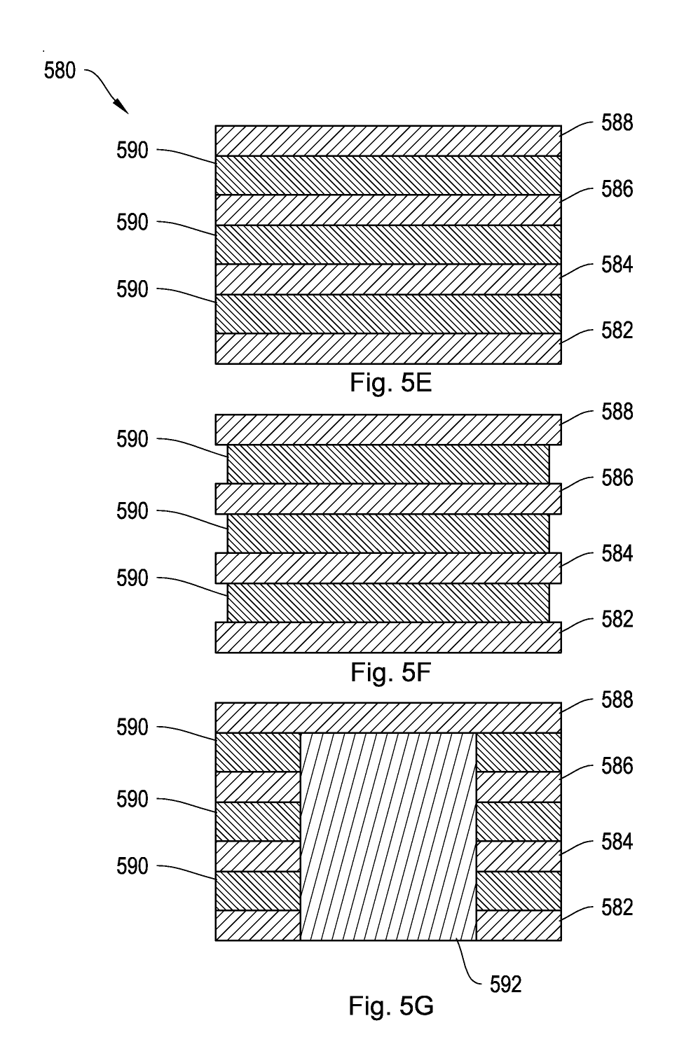

FIG. 5A depicts an illustrative perspective view of a partially fabricated MEMS device of an array. In particular, FIG. 5A illustrates a resonator element 500 fabricated with moving bridge 502 and connected with anchors 504. Anchors 504 are buried in the oxide of Inter Metal Dielectric (IMD) layer 506 to provide support to the resonator element. The deformation or movement of bridge 502 is limited by the yield strength of the metal used to fabricate bridge 502. In one embodiment, the length of bridge 502 ranges from about 50 um to about 100 um. In some embodiments, the length of bridge 502 ranges up to about 300 um.

FIG. 5B depicts an illustrative perspective view of resonator element 500 with capping 552 (element 550). The separation and size of release holes 554 may be more important for MEMS devices fabricated within at most two conductor layers in a stack of interconnection layers. Typical fabrication within most or all layers of the stack are directed towards overetching, since there exist etch blocking structures to prevent undesired etching. However, for the proposed configuration (similar to FIGS. 2A and 2B), a time control to limit the etching may be used. Since the proposed configuration requires the gaseous HF move vertically at most below the second conductor layer, while moving horizontally within the entire MEMS device to release the device, the maximum separation and minimum size of the release holes in the capping need to be carefully considered. If the release holes are too big or too close, there may be no material left after etching to implement the MEMS device. In some embodiments, the release holes array is more dense in configurations similar to that of FIGS. 2A and 2B compared to a configuration similar to that of FIG. 1.

Additionally, the proposed configuration may require anchors 556 for supporting the capping 552, and ensuring that the capping 552 does not bend and damage the MEMS device. In some embodiments, a dense array of anchors 556 is required to support the capping 552. In addition to supporting capping 552, anchors 558 may be used to support the MEMS device. However, need for these anchors may be eliminated by simply burying the MEMS device in a dielectric layer (e.g., silicon dioxide), which is illustrated in FIG. 2B. Since none of the dielectric material has been etched away, the MEMS device will be supported in place by the surrounding dielectric material.

FIGS. 5C-5G show illustrative column anchors for supporting capping 552 and/or the MEMS device. The terms “column” and “anchor” may be used interchangeably for structures that support capping 552 or a MEMS device. FIG. 5C shows an embodiment of column 560 implemented in a stack of metal layers that extends from a top metal layer 568 to metal layer 562. In particular, the column 560 includes metal layer portions 562-568 separated by vias 570 in a stack. The vias may have a square footprint and a fixed size according to design rules of the CMOS processes. Additionally, the metal layer portions may have a minimum overlap from the via. FIG. 5D shows another embodiment of column 560 where vias 570 are extended in order to have a bigger footprint. This may help make the column more robust and provide better support for capping 552 and/or the MEMS device.

FIG. 5E shows a column 580 implemented in a stack of metal layers that extends from a top metal layer 588 to metal layer 582. The column 580 has an extended width of metal layer portions 582-588 and vias 590 compared to column 560, which may help make the column more robust. The metal layer portions and vias may have similar widths (FIG. 5E), or the metal layer portions may have a minimum overlap from the vias according to design rules of the CMOS processes (FIG. 5F). FIG. 5G shows another embodiment of column 580 where a portion of the stack is replaced with dielectric material. The oxide portion may have a square shape or any other suitable shape such that the oxide is not etched away. For example, the top metal layer 588 may not have release holes to preserve the oxide beneath. The combination of metal and oxide may provide better robustness compared to other implementations.

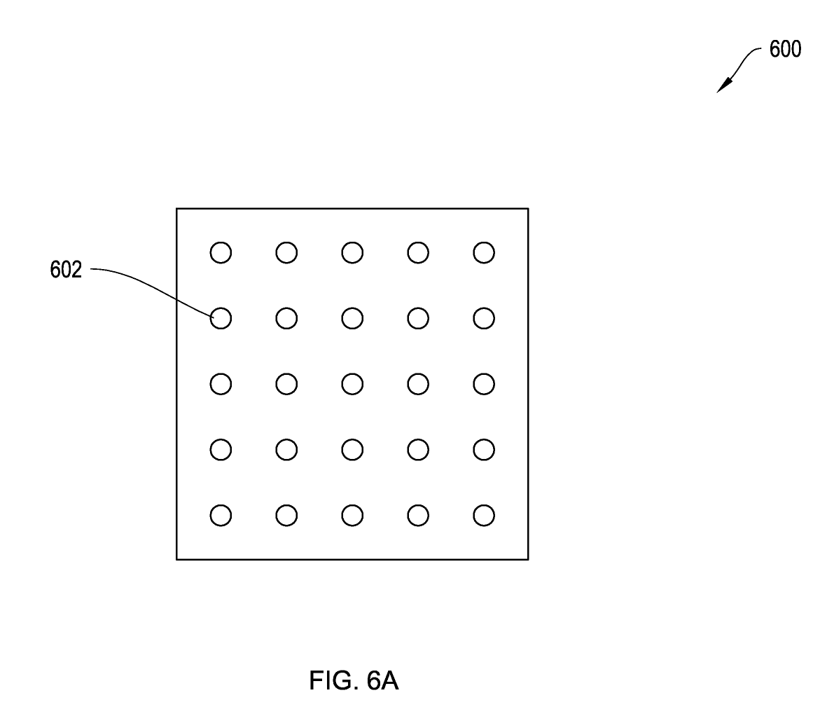

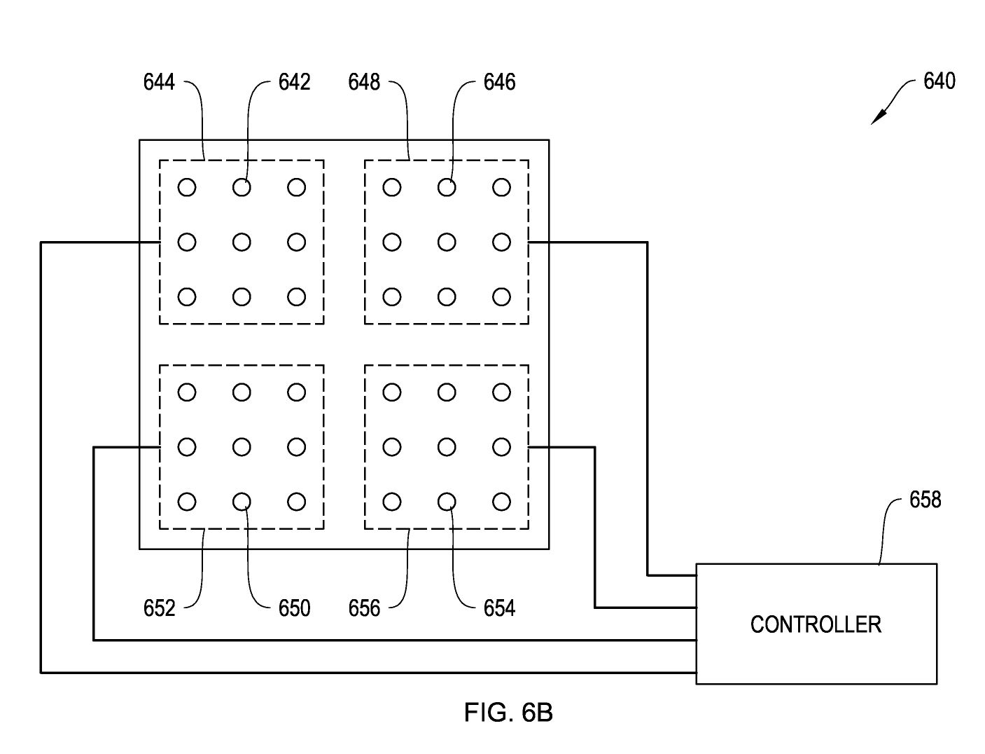

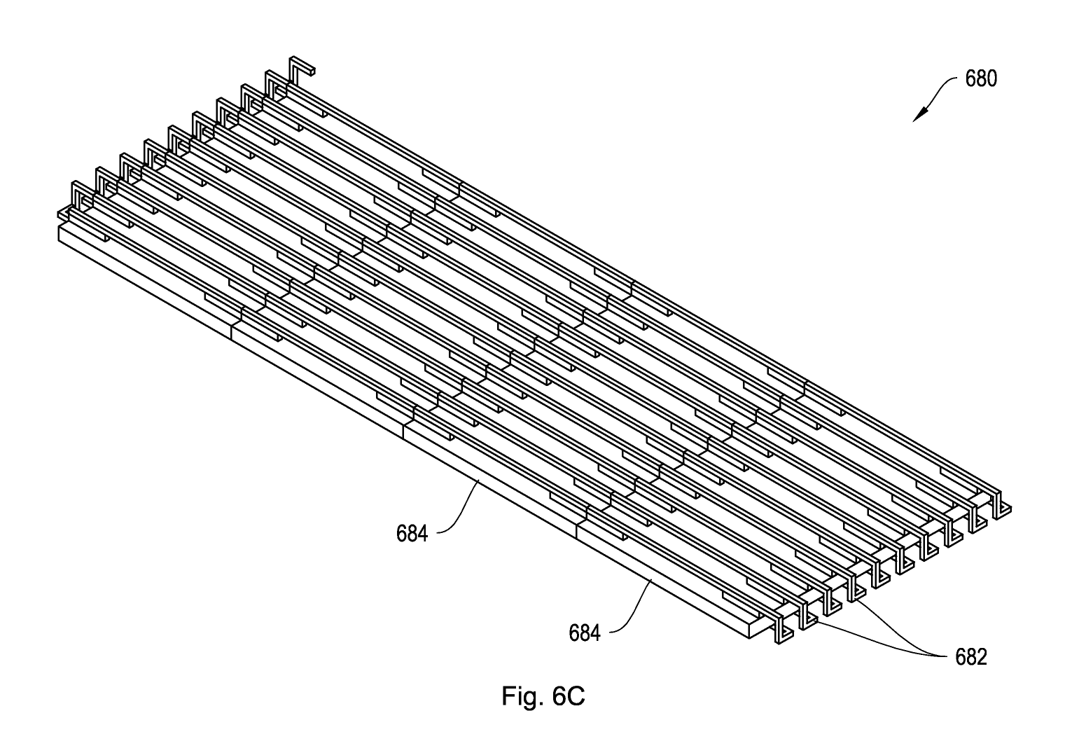

FIG. 6A depicts an illustrative diagrammatic view of an array 600 of MEMS devices 602. In certain cases, a MEMS device fabricated within interconnection layers of an integrated circuit using the described approach may not have the sensitivity required for its intended application. This is because the MEMS element released from the layers of conductor material may not have a sufficient length or mass. For example, a MEMS accelerometer may require a certain proof mass for use in its intended environment. In order to achieve a critical mass or length for the MEMS device to have the target sensitivity, an array of MEMS devices may be fabricated within the interconnection layers. For example, an array of MEMS accelerometers having a appropriate combined proof mass may be used as an accelerometer having the required proof mass.

Furthermore, due to silicon area savings from the described approach, multiple arrays of MEMS devices may be fabricated in the interconnection layers and disposed above an application specific integrated circuit (ASIC) that can selectively control the arrays. In some embodiments, a single type of MEMS device is fabricated above the ASIC. Certain devices may be initially unused and reserved for redundancy in case of failure of another in-use device. In case of failure of a device due to issues during fabrication, the redundant device may help improve yield. In case of failure of a device during operation, the redundant device may help improve long-term reliability.

In some embodiments, a metal layer is etched using a time based stop to form a MEMS device having a moveable plate and attached springs. Since the MEMS device is formed from a single metal layer, a typical moveable plate may bend or collapse with an electrode or surrounding oxide. In such a case, the moveable plate can be split into multiple smaller moveable plates. Consequently, an array of MEMS devices each having a moveable plate and attached springs may be built. Such an array will have an effectively higher stiffness due to the combined stiffness of the springs. However, soft springs may be used to counter the stiffness (described further with respect to FIG. 6C below). Another advantage offered by such an array of MEMS devices made from a single metal layer is that it can be stacked on top of an Application-Specific Integrated Circuit (ASIC) due to its low thickness. In some embodiments, the array of MEMS devices includes redundant elements to improve yield and/or long-term reliability. For example, the array of MEMS devices may include a number of accelerometers. In some embodiments, the array of MEMS devices includes sensors of different types. For example, the array of MEMS devices may include a magnetometer, a gyroscope, and an accelerometer. In another example, the array of MEMS devices may include a 3-D magnetometer, a 3-D gyroscope, and a 3-D accelerometer. In some embodiments, the array of MEMS devices is built on top of an ASIC.

In some embodiments, the MEMS devices include a sensor array of MEMS devices that is configured to collectively operate as a resonator. In some embodiments, the sensor array includes about 60 to about 200 MEMS devices. In some embodiments, the sensor array is densely formed in a small area of the interconnection layers to reduce frequency mismatch between the MEMS devices in the sensor array. In some embodiments, the sensor array has a Q factor of 100 or higher. In some embodiments, the sensor array has a Q factor ranging from about 5 to about 20.

In some embodiments, the MEMS array is used to build a gyroscope. Such a gyroscope may require a large proof mass to be implemented using the MEMS technology. In embodiments where structural layers produced via the MEMS technology are thin, an array of small elements or devices may be produced to provide an effect similar to that of a large proof mass. Such a gyroscope may further require autocalibration to compensate for, e.g., mechanical properties that may change with temperature, aging, usage, and production. In some embodiments, values of the proof mass and capacitances of the gyroscope may be measured and stored, while other parameters, such as vertical and lateral stiffness, may be autocalibrated. In some embodiments, an autocalibration algorithm may be used that does not need measurement or calibration of the proof mass and capacitances.

In some embodiments, the MEMS array is used to build a magnetometer. The magnetometer may be made with an array of small devices (or elements). The array of small devices may minimize bending of structural layers. The array of small devices may simplify etching by, for example, allowing the etching to be shorter and more controllable. Such an array of small devices may provide an aggregate large mass and/or area. The array may allow sensing physical magnitudes with the appropriate sensitivity, and may provide higher reliability than one or more big devices. In some embodiments, the small devices in the array may be nano-magnetometers.

FIG. 6B depicts an illustrative diagrammatic view of a reconfigurable array of MEMS devices. In some embodiments, multiple arrays each having a different type of MEMS device are fabricated and then the ASIC may switch between each array as required. For example, a reconfigurable motion sensor cell 640 may be formed that includes an accelerometer array 644 (including elements 642), a gyroscope array 648 (including elements 646), a compass array 652 (including elements 650), and a magnetometer array 656 (including elements 654) fabricated within the interconnection layers of the ASIC. The motion sensor cell's ASIC controller 658 may then select whether the motion sensor cell should offer the functionality of an accelerometer, a gyro, a compass, or a magnetometer. In some embodiments, a hybrid motion sensor is built having redundant elements as well multiple types of device arrays, thereby offering the combined benefits of reconfigurability, redundancy, and reliability.

FIG. 6C depicts an illustrative perspective view of an array 680 of MEMS devices 682. The devices 682 include anchors 684. In order to fabricate devices, such as magnetometers or inertial sensors, a critical amount of length or mass, respectively, is necessary to achieve a given target sensitivity. In order to achieve this critical mass or length the array 680 may include elements 682 to operate as a single device having the target length or mass.

Since each MEMS device 682 is formed from a single metal layer, a typical moveable plate may bend or collapse with an electrode or surrounding oxide. In such a case, the moveable plate can be split into multiple smaller moveable plates. Consequently, an array of MEMS devices each having a moveable plate and attached springs may be built. Such an array will have an effectively higher stiffness due to the combined stiffness of the springs. However, soft springs may be used to counter the stiffness. Such soft springs are fabricated as thin one-layer springs, which are attached to the moveable plate, and bend together with the moveable plate. As such, since there is no rigid portion to add stiffness, even the combined stiffness of the soft springs may be suitable for allowing the multiple moveable plates to operate together as a single device.

For those devices requiring a large quality factor, Q, e.g., a magnetometer or a gyroscope, if the elements of the array are mechanically decoupled, the Q factor of the array will be low due to the frequency mismatch of the individual elements. The frequency mismatch may result due to process tolerance and different history of use for each individual element. A low Q of the array despite having a high Q of the individual elements may be advantageous in the design of accelerometers, where typically there is a trade off between the high Q required to reduce the brownian noise and the low Q required to reduce a ringing response to a step function and the amplification of high frequency vibrations. With these arrays of mechanically decoupled elements, we can have a high Q for the individual elements, which is what matters to reduce brownian noise, and a low Q of array, which is what matters to avoid amplification of the high frequency vibrations and the ringing of the step response. Applicants have experimentally observed that the values of Q of the array are enough to achieve the sensitivity specs for compelling motion sensors in the consumer space.

Building an array of mechanically coupled elements may be challenging in the case of a magnetometer. Since each element is formed from a single metal layer, any mechanical coupling may electrically short circuit the elements, and the current may not flow in the intended direction. In some embodiments, the elements are joined by means of a high density sublayer of silicon oxide, which will remain unetched while a low density sublayer of oxide will be removed in the same area while the high density sublayer will remain unetched. In order to facilitate etching of a low density sublayer beneath a lower conductor layer, a column may be placed just below a release hole of the top conductor layer. Applicants have observed that such a column may advance gaseous HF faster vertically below the lower conductor layer, and help horizontally etch the target low density sublayer.

In some embodiments, the elements are joined by means of oxide of a metal-insulator-metal (MIM) layer, e.g., silicon nitride enriched with silicon, which may not be etched away easily along with silicon nitride. This may require the addition of MIM capacitors to the array to be implemented between a top conductor layer and a second adjacent conductor layer. In some embodiments, a silicon nitride sublayer found within the inter-metal dielectric layer of certain CMOS processes (e.g., 130 nm or lower CMOS process) is used instead of a MIM layer.

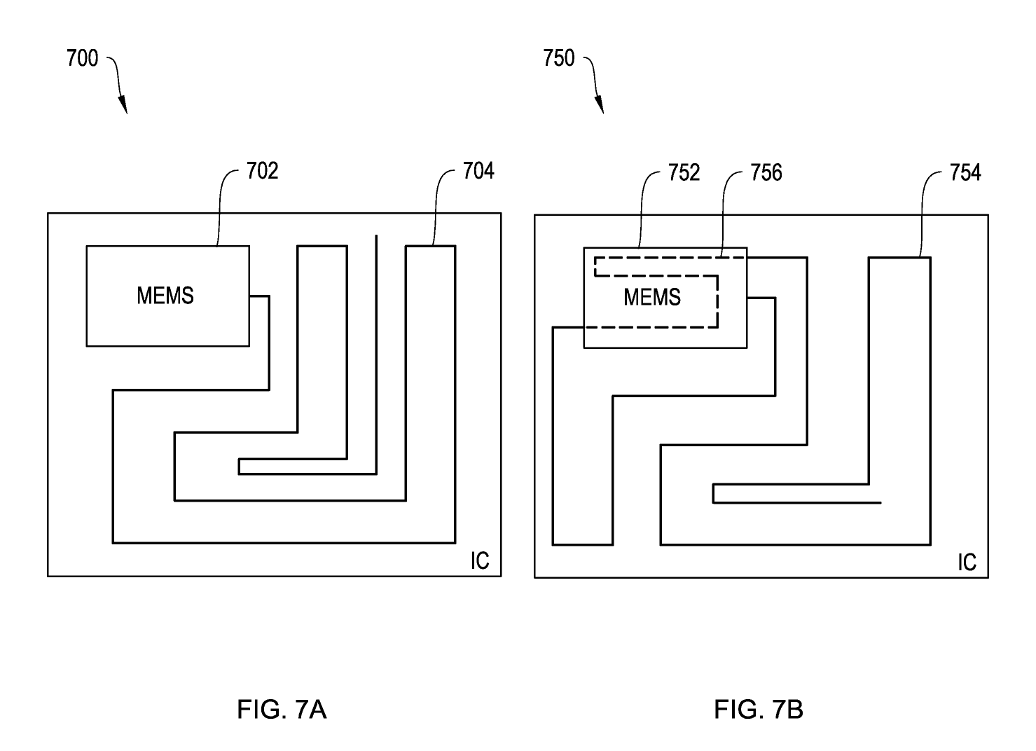

FIG. 7A depicts an illustrative diagrammatic view of a chip 700 having an array of MEMS devices 702 arranged in an integrated circuit. The illustrated chip 700 includes MEMS devices 702 fabricated within the interconnection layers of the integrated circuit using most or all interconnection layers. As a result, this configuration leaves little room in the interconnection layers for routing to and from electronic elements also on the integrated circuit. Instead, additional silicon area needs to be allotted for routing 704 to be implemented. In this configuration, any silicon area of the chip allocated to the MEMS device typically cannot be used for routing and, thus, adds to the silicon area required to fabricate the integrated circuit.

FIG. 7B depicts another illustrative diagrammatic view of a chip 750 having an array of MEMS devices 752 arranged in an integrated circuit. The illustrated chip 750 includes MEMS devices 752 fabricated within the interconnection layers of the integrated circuit using at most two layers of conductor material. As a result, one or more of the remaining layers of conductor material are used for routing connections 756 in addition to routing connections 754 on the chip. Accordingly, MEMS device 752 may be fabricated within a stack of interconnection layers of an integrated circuit while still allowing for routing connections 756 within the lower layers of the stack, thereby reducing silicon area needed for the chip.

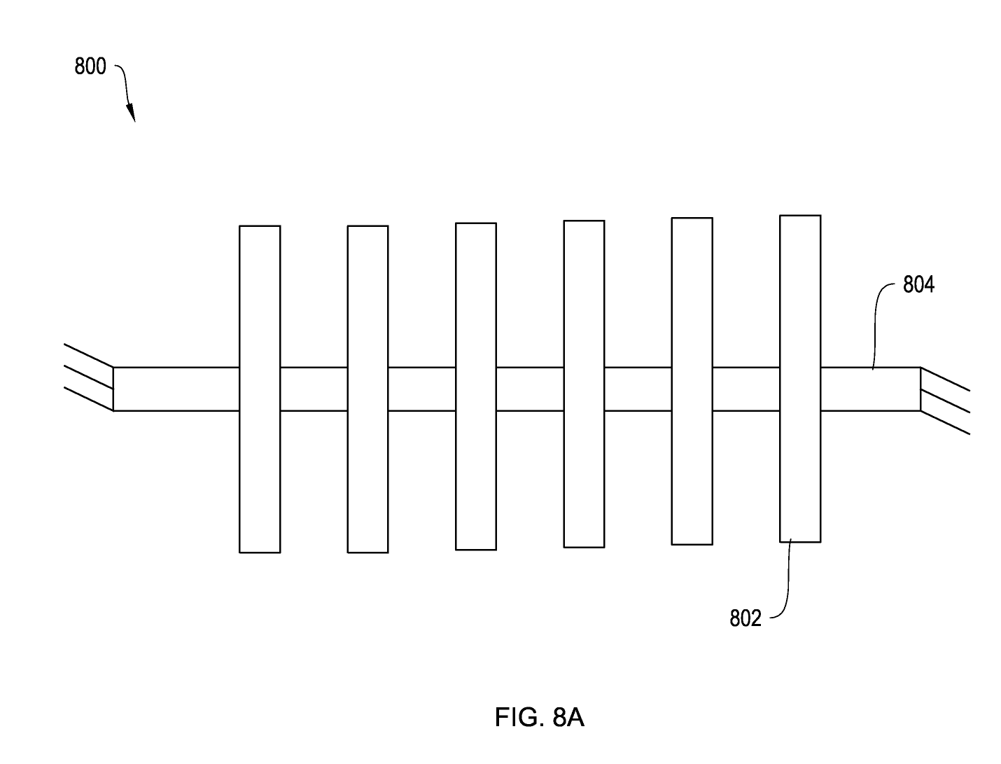

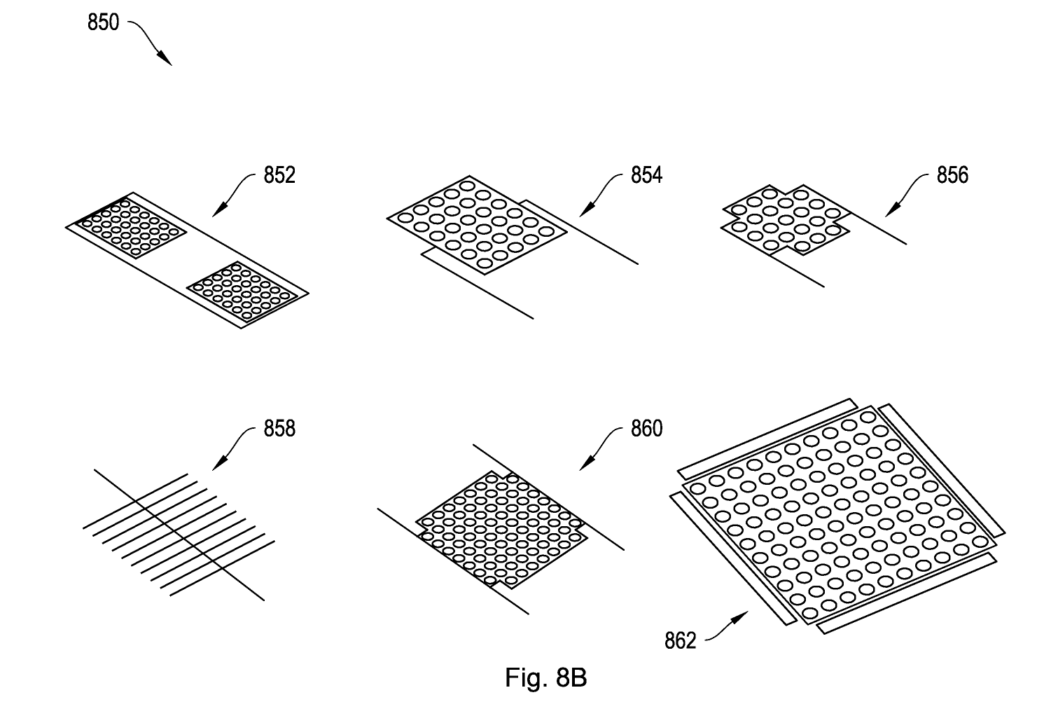

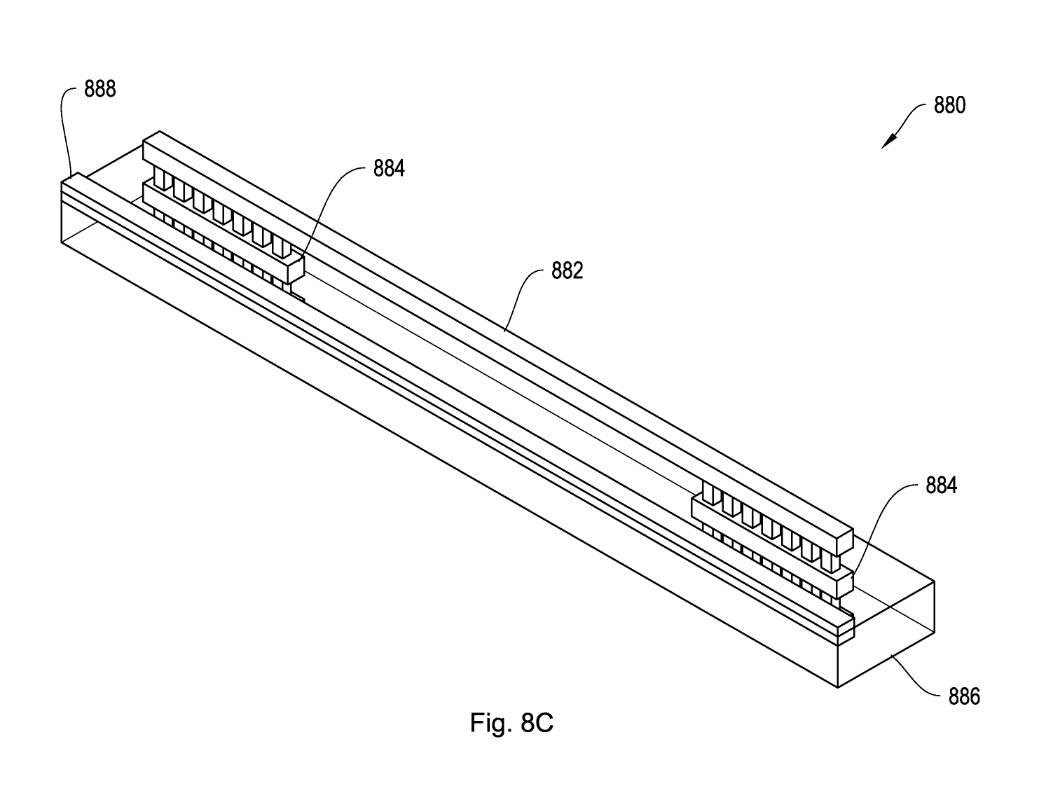

FIGS. 8A and 8B depict illustrative diagrammatic views of various resonator elements. In the case of inertial sensors, it is preferable to maximize the mass of a resonator element in order to reduce the resonant frequency. One such configuration for a resonator element 800 is illustrated in FIG. 8A. The resonator element 800 includes bridge 804 with additional lateral cantilevers 802 to maximize the mass of resonator element 800. This type of resonator element may be used as, e.g., a gyro. Additional configurations 850 for inertial sensors are illustrated in FIG. 8B. As opposed to maximizing mass in case of a gyro, an inertial sensor having minimized area not carrying current is preferable for a magnetometer (to maximize signal-to-noise ratio for brownian noise). Accordingly, any of configurations 852-862 may be useful depending on the type of device under consideration, e.g., a gyro, a compass, a accelerometer, a magnetometer, or any other suitable device. Bridges may be preferred if length needs to be maximized. This is because the Applicant has experimentally verified that the residual stress in the metal layers of the CMOS processes is usually tensile, and hence it tends to keep a large degree of flatness in bridges. For example, bridges may use to build a magnetometer where the current is required to flow in one direction all the time. Since bridges connect in series, the current will flow in one direction only and they are well suited to build a magnetometer. However, if the constraint is reducing frequency mismatch to maximize the quality factor, Q, of the array, then a cantilever-type structure may be a better option.

FIG. 8C depicts an illustrative perspective view of MEMS resonator device 880 including a resonator element 882, supporting members 884 attached to the resonator element 882, and a calibration element 888 disposed proximate to the resonator element 882. In the embodiment shown, the calibration element 888 includes a metal wire disposed proximate to the resonator element 882 in a parallel fashion, and a portion of the calibration element 888 is disposed in an unetched layer of dielectric material 886. In some embodiments, the calibration element includes an inductor disposed proximate to the resonator element. The resonator element is calibrated based on a magnetic field generated on passing current through the calibration element.

The resonator element 882 is formed within a first layer of conductor material. The calibration element 888 is formed within a second adjacent and lower layer of conductor material. The resonator element 882 is further calibrated based on a capacitance generated between the first layer of conductor material and the second layer of conductor material. The capacitance aids in determining a distance between the calibration element and the resonator element.

In some embodiments, the MEMS resonator device 880 further includes a first capacitive element disposed within the first layer of conductor material, and a second capacitive element disposed within the second adjacent layer of conductor material. The resonator element 882 is further calibrated based on a first capacitance of the first capacitive element. The first capacitance aids in determining a thickness of the first layer of conductor material. The resonator element 882 is further calibrated based on a second capacitance of the second capacitive element. The second capacitance aids in determining a thickness of the second layer of conductor material.

In some embodiments, the resonator element includes a magnetometer, and calibrating the resonator element includes calibrating a gain of the magnetometer. However, in addition to the gain, an offset of the magnetometer may need to be calibrated as well. This may be desirable to avoid a high offset that saturates the detection chain, or requires an unfeasible front end with an unrealistic high dynamic range and to avoid a constant or fixed error in the output.

There may be two sources of magnetometer offset. The first source may be the electronic elements. This offset may be measured by turning off the Lorentz current, such that no magnetic force is generated. The second source may be electrostatic force that is added to the magnetic force. The electrostatic force is proportional to the square of the voltage. If there is a DC and a AC voltage component (Vdc and Vac) at frequency f0, the square will generate electrostatic force components at DC, f0 and 2*f0. The magnetic force will only have a component at f0 (since the Lorentz current is an AC current at f0, the resonant frequency of the resonator element). Therefore, there is a component of the electrostatic force that will sum with the magnetic force, adding an offset, since this will be a constant term irrespective of the magnetic force.

This term of the electrostatic force at f0 is proportional to Vdc*Vac. Since Vac appears because of the voltage drop of the Lorentz current through the resistances of the resonator element, it cannot be eliminated. Instead Vdc may be reduced as close to zero as possible. For example, a Vdc of 10 uV may suffice in order to have a contribution almost below the noise level of the magnetometer having about 1 uT. A problem may be that the offset of electronic elements is typically in the 20-50 mV, so it may not be possible to control that DC voltage, at least in an open loop.

In some embodiments, a digital-to-analog converter (DAC) may be used to try different voltages until we arrive at the required voltage. In order to determine the required DC voltage from the DAC such that Vdc is close to zero (e.g., between about −10 uV and about +10 uV), we sense the effect of Vdc. This may be accomplished by placing an electrode, either below the resonator element (for out-of plane vibration, i.e., X or Y magnetic field components) or parallel to the resonator element (for in-plane vibration, i.e., Z magnetic field component). The electrode may be actuated electrostatically with an AC signal at a frequency fc, such that the bridge has some deflection at this frequency fc. This modulates the electrostatic force component but not the magnetic component, helping distinguish the two components. Subsequently, the voltage of the DAC is adjusted such that this spectral component of the current sensed, which will be located at a fc distance from the magnetic force, is minimized. Alternatively, determining the required DC voltage may be accomplished by adding a DC voltage, applying two different voltages, and solving a system of equations to solve for the required voltage value.

Applicants consider all operable combinations of the embodiments disclosed herein to be patentable subject matter. Those skilled in the art will know or be able to ascertain using no more than routine experimentation, many equivalents to the embodiments and practices described herein. Accordingly, it will be understood that the systems and methods described herein are not to be limited to the embodiments disclosed herein, but is to be understood from the following claims, which are to be interpreted as broadly as allowed under the law. It should also be noted that, while the following claims are arranged in a particular way such that certain claims depend from other claims, either directly or indirectly, any of the following claims may depend from any other of the following claims, either directly or indirectly to realize any one of the various embodiments described herein.

What is claimed is:

1. A method for manufacturing a chip comprising a plurality of MEMS devices arranged in an integrated circuit comprising:
forming electronic elements on a semiconductor material substrate;
forming, above the semiconductor material substrate, a stack of interconnection layers including a plurality of layers of conductor material, each layer separated by a layer of dielectric material; and
forming the plurality of MEMS devices within the stack of interconnection layers by applying gaseous HF to a first layer of dielectric material positioned highest in the stack of interconnection layers, while allowing at least one layer of dielectric material to remain unetched, and allowing at least one layer of conductor material for routing connections to and from the electronic elements.

2. The method of claim 1, wherein the unetched layer of the dielectric material is the lowest layer of the dielectric material in the stack.

3. The method of claim 1, wherein the chip is manufactured using a 180 nm or lower CMOS process.

4. The method of claim 3, wherein the chip is manufactured using one of a 22 nm CMOS process, a 32 nm CMOS process, a 45 nm CMOS process, and a 65 nm CMOS process.

5. The method of claim 1, wherein the highest layer of conductor material in the stack includes aluminum.

6. The method of claim 1, wherein the first layer of dielectric material includes silicon dioxide.

7. The method of claim 1, further comprising forming at least one anchor within the layers of conductor material for supporting a MEMS device of the plurality of MEMS devices or a top layer of the plurality of layers of conductor material.

8. The method of claim 1, wherein the plurality of MEMS devices are of a same type.

9. The method of claim 8, wherein the plurality of MEMS devices comprises a first device and second device, and the second device is reserved for redundancy in case of failure of the first device.

10. The method of claim 1, wherein the plurality of MEMS devices are of different types including at least one of a magnetometer, a gyroscope, and an accelerometer.

11. The method of claim 1, wherein the plurality of MEMS devices comprise a sensor array of MEMS devices, the sensor array configured to collectively operate as a resonator.

12. The method of claim 11, wherein the sensor array comprises about 60 to about 200 MEMS devices.

13. The method of claim 1, wherein the sensor array includes a first plurality of MEMS devices configured to collectively operate as a first type of device and a second plurality of MEMS devices configured to collectively operate as a second type of device, wherein the sensor array is reconfigurable from operating as the first type of device to operating as the second type of device.

14. The method of claim 11, wherein the sensor array is densely formed in a small area of the interconnection layers to reduce frequency mismatch between the MEMS devices in the sensor array.

15. The method of claim 13, wherein the sensor array has a Q factor of 100 or higher.

16. The method of claim 13, wherein the sensor array has a Q factor ranging from about 5 to about 20.

17. A chip comprising a plurality of MEMS devices arranged in an integrated circuit comprising:
electronic elements formed on a semiconductor material substrate;
a stack of interconnection layers, produced above the semiconductor material substrate, including a plurality of layers of conductor material, each layer separated by a layer of dielectric material; and
the plurality of MEMS devices formed within the stack of interconnection layers by applying gaseous HF to a first layer of dielectric material positioned highest in the stack of interconnection layers, while allowing at least one layer of dielectric material to remain unetched, and allowing at least one layer of conductor material for routing connections to and from the electronic elements.

18. The chip of claim 17, wherein the unetched layer of the dielectric material is the lowest layer of the dielectric material in the stack.

19. The chip of claim 17, wherein the chip is manufactured using a 180 nm or lower CMOS process.

20. The chip of claim 19, wherein the chip is manufactured using one of a 22 nm CMOS process, a 32 nm CMOS process, a 45 nm CMOS process, and a 65 nm CMOS process.

21. The chip of claim 17, wherein the highest layer of conductor material in the stack includes aluminum.

22. The chip of claim 17, wherein the first layer of dielectric material includes silicon dioxide.

23. The chip of claim 17, further comprising at least one anchor within the layers of conductor material for supporting a MEMS device of the plurality of MEMS devices or a top layer of the plurality of layers of conductor material.

24. The chip of claim 17, wherein the plurality of MEMS devices are of a same type.

25. The chip of claim 24, wherein the plurality of MEMS devices comprises a first device and second device, and the second device is reserved for redundancy in case of failure of the first device.

26. The chip of claim 17, wherein the plurality of MEMS devices are of different types including at least one of a magnetometer, a gyroscope, and an accelerometer.

27. The chip of claim 17, wherein the plurality of MEMS devices comprise a sensor array of MEMS devices, the sensor array configured to collectively operate as a resonator.

28. The chip of claim 27, wherein the sensor array comprises about 60 to about 200 MEMS devices.

29. The chip of claim 17, wherein the sensor array includes a first plurality of MEMS devices configured to collectively operate as a first type of device and a second plurality of MEMS devices configured to collectively operate as a second type of device, wherein the sensor array is reconfigurable from operating as the first type of device to operating as the second type of device.

30. The chip of claim 29, wherein the sensor array is densely formed in a small area of the interconnection layers to reduce frequency mismatch between the MEMS devices in the sensor array.

31. The chip of claim 29, wherein the sensor array has a Q factor of 100 or higher.

32. The chip of claim 29, wherein the sensor array has a Q factor ranging from about 5 to about 20.

33. A method for manufacturing a chip comprising a plurality of MEMS devices arranged in an integrated circuit comprising:
forming electronic elements on a semiconductor material substrate;
forming, above the semiconductor material substrate, a stack of interconnection layers including a plurality of layers of conductor material, each layer separated by a layer of dielectric material; and
forming the plurality of MEMS devices within the stack of interconnection layers by applying gaseous HF to a first layer of dielectric material positioned highest in the stack of interconnection layers, while allowing at least one layer of dielectric material to remain unetched,
wherein the chip is manufactured in a CMOS process including low-k dielectric material having a dielectric constant lower than silicon dioxide, and
wherein the first layer of dielectric material includes silicon dioxide and the at least one unetched layer of dielectric material includes low-k dielectric material.

34. The method of claim 33, wherein the CMOS process is a 130 nm or lower CMOS process.

35. A CMOS MEMS integrated circuit chip comprising:
electronic elements formed on a semiconductor material substrate;
a stack of interconnection layers, arranged above the semiconductor material substrate, including a plurality of layers of conductor material, each layer separated by a layer of dielectric material;
a plurality of MEMS devices formed within the stack of interconnection layers by applying gaseous HF to a portion of a first layer of dielectric material positioned highest in the stack of interconnection layers, the first layer of dielectric material including silicon dioxide; and
at least one layer of unetched dielectric material including low-k dielectric material, the low-k dielectric material having a dielectric constant lower than silicon dioxide.

36. The chip of claim 35, wherein the plurality of MEMS devices are formed using a 130 nm or lower CMOS process.

37. A MEMS resonator device, comprising:
a resonator element;
at least one supporting member attached to the resonator element; and
a calibration element disposed proximate to the resonator element;
wherein the resonator element is calibrated based on a magnetic field generated on passing current through the calibration element.

38. The device of claim 37, wherein
the resonator element is formed within a first layer of conductor material,
the calibration element is formed within a second adjacent layer of conductor material, and
the resonator element is further calibrated based on a capacitance generated between the first layer of conductor material and the second layer of conductor material, wherein the capacitance aids in determining a distance between the calibration element and the resonator element.

39. The device of claim 38, further comprising:
a first capacitive element disposed within the first layer of conductor material; and
a second capacitive element disposed within the second adjacent layer of conductor material;
wherein the resonator element is further calibrated based on a first capacitance of the first capacitive element, the first capacitance aiding in determining a thickness of the first layer of conductor material, and
wherein the resonator element is further calibrated based on a second capacitance of the second capacitive element, the second capacitance aiding in determining a thickness of the second layer of conductor material.

40. The device of claim 37, wherein the calibration element includes a metal wire disposed proximate to the resonator element in a parallel fashion.

41. The device of claim 37, wherein the calibration element includes an inductor disposed proximate to the resonator element.

42. The device of claim 37, wherein a portion of the calibration element is disposed in an unetched layer of dielectric material.

43. The device of claim 37, wherein the resonator element includes a magnetometer, and calibrating the resonator element includes calibrating a gain of the magnetometer.

44. A method of calibrating a MEMS resonator device, comprising:
providing the MEMS resonator device, including:
a resonator element formed within a first layer of conductor material,
at least one supporting member attached to the resonator element, and
a calibration element formed within a second adjacent layer of conductor material, the calibration element disposed proximate to the resonator element;
applying a current to the calibration element to generate a magnetic field;
measuring a capacitance generated between the first layer of conductor material and the second layer of conductor material, wherein the capacitance aids in determining a distance between the calibration element and the resonator element; and
calibrating the resonator element based on the magnetic field and the measured capacitance.

45. The method of claim 44, wherein the MEMS resonator device includes a first capacitive element disposed within the first layer of conductor material, and a second capacitive element disposed within the second adjacent layer of conductor material, the method further comprising:
calibrating the resonator element based on a first capacitance of the first capacitive element, the first capacitance aiding in determining a thickness of the first layer of conductor material, and
calibrating the resonator element based on a second capacitance of the second capacitive element, the second capacitance aiding in determining a thickness of the second layer of conductor material.

46. A method for manufacturing a chip comprising a plurality of anchors arranged in an integrated circuit comprising:
forming electronic elements on a semiconductor material substrate;
forming, above the semiconductor material substrate, a stack of interconnection layers including a plurality of layers of conductor material, each layer separated by a layer of dielectric material; and
forming the plurality of anchors within the stack of interconnection layers by applying gaseous HF to a first layer of dielectric material in the stack of interconnection layers, while allowing at least one layer of dielectric material to remain unetched, and allowing at least one layer of conductor material for routing connections to and from the electronic elements,
wherein each anchor includes at least one conductor layer portion from the layers of conductor material separated by one or more vias, and
wherein each anchor supports a top layer of the plurality of layers of conductor material or a MEMS device formed within the stack of interconnection layers.

47. The method of claim 46, wherein a portion of at least one anchor of the plurality of anchors includes dielectric material replacing conductor material or via.

48. The method of claim 46, wherein at least one anchor of the plurality of anchors is formed according to a CMOS process design rule violation.

49. The method of claim 48, wherein the design rule violation includes conductor layer portions and vias that are substantially similar in width and do not overlap.

50. The method of claim 48, wherein the design rule violation includes vias that are wider than a width according to the CMOS process.

51. A chip comprising a plurality of anchors arranged in an integrated circuit comprising:
electronic elements formed on a semiconductor material substrate;
a stack of interconnection layers, formed above the semiconductor material substrate, including a plurality of layers of conductor material, each layer separated by a layer of dielectric material; and
the plurality of anchors formed within the stack of interconnection layers by applying gaseous HF to a first layer of dielectric material in the stack of interconnection layers, while allowing at least one layer of dielectric material to remain unetched, and allowing at least one layer of conductor material for routing connections to and from the electronic elements,
wherein each anchor includes at least one conductor layer portion from the layers of conductor material separated by one or more vias, and
wherein each anchor supports a top layer of the plurality of layers of conductor material or a MEMS device formed within the stack of interconnection layers.

52. The chip of claim 51, wherein a portion of at least one anchor of the plurality of anchors includes dielectric material replacing conductor material or via.

53. The chip of claim 51, wherein at least one anchor of the plurality of anchors is formed according to a CMOS process design rule violation.

54. The chip of claim 53, wherein the design rule violation includes conductor layer portions and vias that are substantially similar in width and do not overlap.

55. The chip of claim 53, wherein the design rule violation includes vias that are wider than a width according to the CMOS process.
